(19) United States
(12) Patent Application Publication
(10) Pub. No.: US 2020/0029445 A1
(43) Pub. Date: Jan. 23, 2020

(54) METHOD OF FORMING CAVITY IN PRINTED CIRCUIT BOARD BY USING RELEASE FILM

(71) Applicant: TLB Co., Gyeonggi-do (KR)

(72) Inventors: Bum-Seok Kim, Gyeonggi-do (KR); Dae-Soo Park, Gyeonggi-do (KR)

(21) Appl. No.: 16/223,466

(22) Filed: Dec. 18, 2018

(30) Foreign Application Priority Data
Jul. 18, 2018 (KR) 10-2018-0083615

(51) Int. Cl. H05K 3/46; H05K 1/03; H05K 3/02; H05K 3/04

(52) U.S. Cl. CPC H05K 3/4697; H05K 1/0366; H05K 3/048; H05K 3/022; H05K 1/0373

(57) ABSTRACT

Disclosed is a cavity forming method for a printed circuit board. The method includes: stacking a plurality of substrates to form a stacked structure, each substrate including a prepreg and a copper clad circuit formed on a surface of the prepreg; attaching a release film to an outer surface of the stacked structure; demarcating a cavity region by forming a cutting line in the release film and the underlying prepreg; and removing the released film and the underlying prepreg inside the demarcated cavity region, thereby forming a cavity. The method is advantageous in terms of easy processing, mass production, and low manufacturing cost for printed circuit boards. Further, a cavity having an exactly same size as an actually required size can be designed for a printed circuit board, and it is possible to prevent an adhesive component from seeping out into a cavity from prepregs during formation of the cavity.

### CROSS REFERENCE TO RELATED APPLICATION

The present application claims priority to Korean Patent Application No. 10-2018-0083615, filed Jul. 18, 2018, the entire contents of which is incorporated herein for all purposes by this reference.

### BACKGROUND OF THE INVENTION

### Field of the Invention

The present invention relates to a method of forming a cavity in a printed circuit board. More particularly, the present invention relates to a method of forming a cavity in a printed circuit board, the method being easy to perform, being suitable for mass production of printed circuit boards, being capable of suppressing an adhesive component from seeping out from a prepreg during a cavity formation process, and being capable of allowing engineers to design the same size cavity as a cavity that is actually required.

### Description of the Related Art

Recently, electronics-related technologies have been focused on development of multi-functional and high-speed electronic products. Responding to this trend, semiconductor chip manufacturing technologies have been extensively researched and developed.

In particular, printed circuit boards (PCBs) are required to respond to the trend of thinner, smaller, and lighter electronic products. To this end, the thickness of PCBs is increasingly reduced. Thus, technology related to a multi-layer printed circuit board is under active research and development to form a number of circuit layers in a printed circuit board.

Typically, a multi-layer printed circuit board is manufactured by stacking a plurality of printed circuit boards, each being composed of a prepreg (an insulator) which is prepared by impregnating glass fibers with an epoxy and copper-clad circuits provided on the prepreg, and then by subjecting the stack of printed circuit boards to hot pressing.

On the other hand, there is a case where some components such as a memory chip are mounted on a multi-layer printed circuit board. In this case, to reduce the thickness of the multi-layer printed circuit board, the board is machined to have a cavity (i.e., recess) so that additional components can be mounted in the cavity.

FIG. 1 is a cross-sectional view illustrating a process of forming a cavity 120 in a multi-layer printed circuit board 100 according to a conventional art.

Conventionally, the cavity is formed using a laser drilling method after an outermost layer 130 is formed. In order to control the depth of the cavity through the laser drilling, a copper clad 122 to reflect laser beams is preliminarily formed in the desired depth.

The copper clad 122 is removed in the process of forming a connection circuit 124 in the cavity 120 after the cavity 120 is formed by the laser drilling.

However, due to inevitable actual machining errors, the residue 122-2 of the copper clad 122 undesirably remains in the vicinity of the cavity 120. In order to connect the connection circuit 124 formed in the cavity with a circuit 114 formed in another region without causing a short circuit, a via hole 126 extending in a thickness direction of the prepreg needs to be carefully formed and the inside of the via hole 126 is plated with a conductive material while preventing any circuit or conductive material from being connected with the copper clad residue 122-2.

This concern is a factor of remarkably reducing the cavity formation yield and increasing the defect rate.

In addition, there is a problem that the adhesive component seeps out from the adjacent prepreg 110 due to the pressure and heat applied during the laser drilling process.

In order to prevent such a phenomenon, a non-flow prepreg manufactured so as to minimize an adhesive flow is used. However, even though a non-flow prepreg is used, a liquid component containing an adhesive component included in the prepreg seeps out during a cavity formation process. Therefore, taking such a phenomenon into consideration, the design dimensions of the cavity 120 are set to be slightly larger than actually required dimensions.

That is, even though an adhesive component seeps out slightly from the prepreg 110, specifically from the boundary (the corner of the cavity), into the cavity 120, the remaining area (i.e., adhesive component-free area) of the cavity satisfies a desired cavity size required for component mounting.

This point is the cause of increasing design dimensions of the cavity 120 more than required and hence increasing machining dimensions of the cavity 120. Therefore, additional work is required to form the cavity having an actually required size. This results in a decrease in the production yield.

In addition, a liquid component seeps into the cavity 120 from the wall surface (the side surfaces of the prepregs 110 and 130), and the prepregs 110 and 130 near the cavity 120 subside, thereby causing the flexure of the multi-layer printed circuit board.

Thus, a circuit portion formed on the outermost layer substrate 130 located on the prepreg having collapsed is likely to be disconnected from an electronic component connected thereto, resulting in that the defect rate increases.

### SUMMARY OF THE INVENTION

The present invention has been made in view of the problems occurring in the related art and an objective of the present invention is to provide a method of forming a cavity in a printed circuit board using a release film, the method having advantages of easy processing and being suitable for mass production of printed circuit boards.

Another objective of the present invention is to provide a method of forming a cavity in a printed circuit board using a release film that is configured to prevent an adhesive component from seeping out into the cavity from prepregs during formation of the cavity.

A further objective of the present invention is to provide a method of forming a cavity in a printed circuit board, the method allowing design dimensions of a cavity in a printed circuit board to be equal to actually required dimensions and preventing prepregs from collapsing.

In order to accomplish the objectives of the present invention, according to one aspect, there is provided a method of forming a cavity in a printed circuit board by using a release film, the method including: stacking a plurality of substrates to form a stacked structure, each substrate including a prepreg and a copper clad circuit formed on the prepreg; attaching a release on an outer surface of the stacked structure; demarcating a cavity region by forming a cutting line in the release film and the prepreg in the stacked structure; and removing the release film and the prepreg inside the cavity region demarcated by the cutting line.

Preferably, the release film and the prepreg may be cut simultaneously by using a die.

The cutting line may be formed by using a cutting jig.

Here, the multiple prepregs may be cut at the same time.

The method may further include performing selective etching on a bottom surface of the cavity to form a circuit.

Preferably, in the method, an adhesive strength between the release film and the prepreg may be stronger than an adhesive strength between each of the prepregs.

The method may further include stacking a terminal connection substrate to be connected with an external component on the outer surface of the remaining release film.

The method is advantageous in terms of easy processing, mass production, and low manufacturing cost for printed circuit boards.

Further, a cavity having an exactly same size as an actually required size can be designed for a printed circuit board, and it is possible to prevent an adhesive component from seeping out into a cavity from prepregs during formation of the cavity.

In addition, it is possible to prevent a poor connection between components attributable to collapsing of the prepregs.

### BRIEF DESCRIPTION OF THE DRAWINGS

The accompanying drawings are provided to aid understanding of the technical spirit of the present invention in conjunction with a detailed description section of the present invention. Therefore, the present invention should not be construed to be limited to the details illustrated in the drawings. In the accompanying drawings:

FIG. 1 is a diagram illustrating a process of forming a cavity in a printed circuit board according to a conventional art;

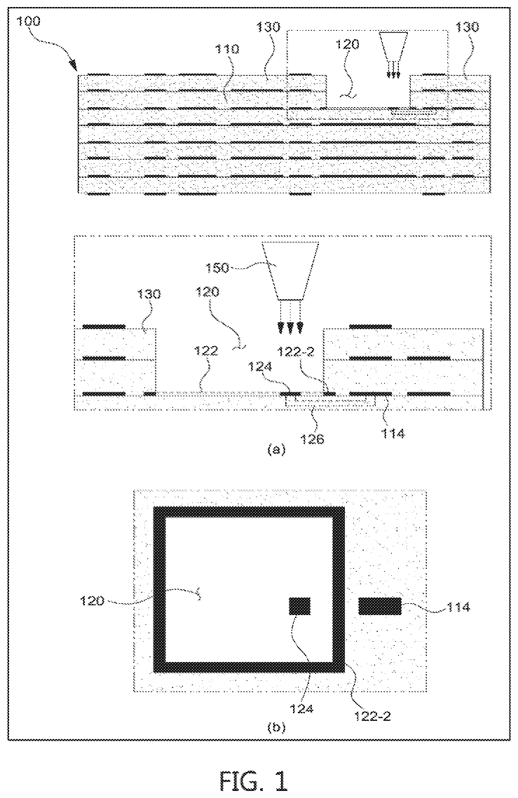

FIG. 2 is a diagram illustrating a process of forming a cavity in a printed circuit board by using a release film, according to one embodiment of the present invention;

FIG. 3 is a flowchart illustrating the sequence of the method; and

FIG. 4 is a side view of the release film used in the method.

### DETAILED DESCRIPTION OF THE DISCLOSURE

Hereinbelow, exemplary embodiments of the present invention will be described in detail with reference to the accompanying drawings.

Prior to giving the following detailed description of the present disclosure, it should be noted that terms used in the specification and the claims should not be construed as being limited to ordinary meanings or dictionary definitions but should be construed in a sense and concept consistent with the technical idea of the present disclosure, on the basis that the inventor can properly define the concept of a term to describe his or her invention in best way possible.

Meanwhile, the exemplary embodiments described in the specification and the configurations illustrated in the drawings are merely examples and do not exhaustively present the technical spirit of the present invention. Accordingly, it should be appreciated that there may be various equivalents and modifications that can replace the exemplary embodiments and the configurations at the time at which the present application is filed.

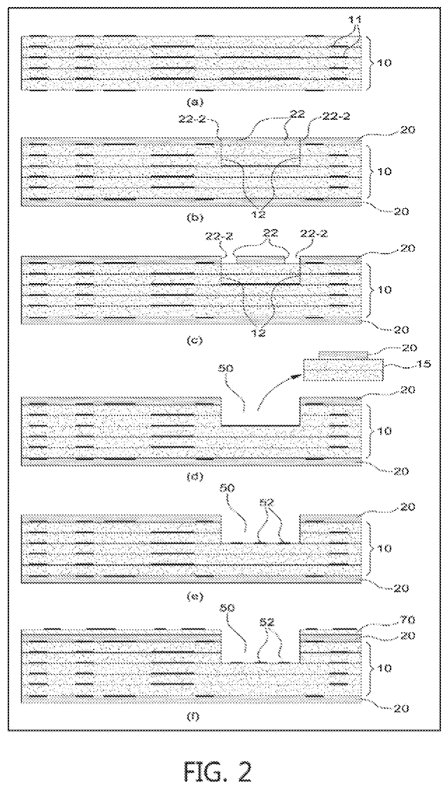

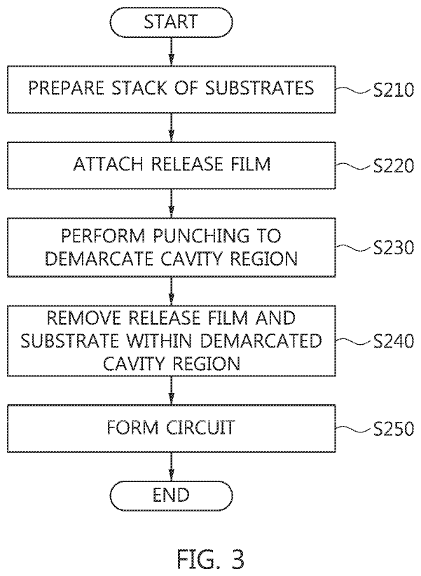

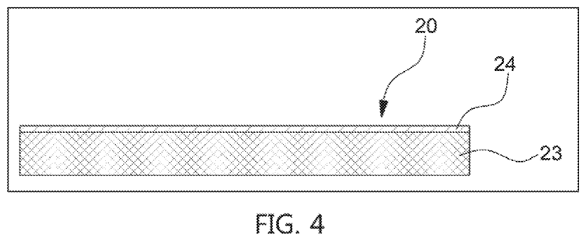

FIG. 2 is a diagram illustrating a process of forming a cavity of a printed circuit board using a release film according to the present invention. FIG. 3 is a flowchart of the method of FIG. 2. FIG. 4 is a side view illustrating the release film used in the method of FIG. 2.

Referring to FIGS. 2 and 3, according to the present invention, a method (hereinafter, simply referred to as the invention method) of forming a cavity in a printed circuit board using a release film, includes: preparing a stack of substrates 10 by stacking the substrates 10 one on another (Step S210); attaching a release film 20 to a surface of the stack of substrates 10 (Step S220); locally cutting along a region of the release film 20 and prepregs underlying the region of the release film 20 (Step S230); and removing the release film 20 and the prepregs within the region (Step S240).

Each of the substrates 10 is manufactured by preparing the prepreg, forming a copper clad on the prepreg, attaching a dry film on a surface of the copper clad, and forming circuits 11 by performing exposure, development, and copper clad etching. The multiple substrates 10 prepared in the way described above are stacked in a thickness direction, and pressure and heat are applied to the stacked multiple substrates 10 to form the stack of substrates 10.

The prepreg is formed by impregnating a polymeric resin into a reinforcing member, such as glass fibers. The reinforcing members include glass fiber cloth, glass fiber nonwoven fabric, carbon fiber cloth, and organic polymer fiber cloth.

In addition, a polymer region that is a material for preparing the prepreg is blended with additives such as a curing agent for adjusting a dielectric constant, a thermal expansion coefficient, and a curing time.

As the additives to be blended with the polymer resin for the property control, inorganic fillers such as silica, aluminum hydroxide, calcium carbonate, and organic fillers such as curing epoxy and crosslinked acryl are available.

The copper clad circuit patterns 11 formed on the respective substrates have a thickness within a range of 15 to 20 μm.

After the multiple substrates 10 are stacked to form a stack (after Step S210), as illustrated in (b) of FIG. 2, the release films 20 are attached to the respective principal surfaces of the stack of substrates 10 (Step S220).

As illustrated in FIG. 4, the release film 4 is prepared by applying an adhesive 24 to a surface of a base member 23 made of Polyethylene Terephthalate (PET) resin. One example of the adhesive 24 is a silicone-based adhesive.

In addition, the base member 20 has a thickness in the range of 18 to 22 jam, the adhesive 24 has a thickness of 5 μm.

The adhesion of the adhesive 24 is preferably set such that the adhesive strength between the release film 20 and the stack of substrates 10 is stronger than the adhesive strength between each of the prepregs in the stack of substrates 10.

As illustrated in (b) of FIG. 2, the release films are attached to the respective outermost surfaces (i.e., an upper surface and a lower surface) of the stack of substrates 10, and then the stack of substrates 10 is placed inside a die.

Then, by punching with a blade which is installed in the die, a region of the release film 20 and the prepregs underlying the release film 20 is cut.

In the process of cutting (i.e., punching) a region of the release film 20 and the underlying prepregs, a cutting jig can be used.

In the process, a cutting line 22 for punching only the release film 20 and a cutting line 22-2 and 12 extending from surface of the release film 20 up to a desired cavity depth are formed at the same time, using the cutting jig.

In the process, the cutting line 12 is formed to have a depth corresponding to the thickness of only one prepreg included in the stack of substrates 10 or a depth corresponding to the total thickness of several prepregs included in the stack of substrates 10.

Preferably, it is desirable to form the cutting line 12 to a depth corresponding to the total thickness of two or three prepregs.

As illustrated in (c) of FIG. 2, the release film 20 between the cutting line 22 having a relatively small size and the cutting line 22-2 having a relatively large size is first removed.

Next, as illustrated in (d) of FIG. 2, the release film 20 inside the cutting line having the relatively small size and the prepregs 15 that are cut in the preceding process are removed, thereby forming a cavity 50.

Then, a copper clad formed on the bottom surface of the cavity is selectively etched to form a circuit 52.

Next, a terminal connection substrate 70 is stacked on the surface of the remaining release film 20.

The terminal connection substrate 70 is, for example, a substrate for connection with external input/output (IO) terminals.

In short, the cavity-forming method according to the present invention includes applying a release film on an outer surface of a stack of substrates, drying the stack, putting the dried stack in a die, forming a cutting line demarcating a cavity region in the release film and the stack by using a blade installed inside the die, and removing the release film and prepregs included in the stack, within the region demarcated by the cutting line. That is, since a thermal process such as laser machining is performed during the formation of the cavity, an adhesive component seeps out from the prepregs into the cavity.

Thus, it is possible to design a cavity having an actually required dimension.

In the case where a large number of cavities are formed in a printed circuit board and the case where a large number of cavities are formed by laser processing, the processing yield is low because the cavities are individually machined. However, according to the present invention, a large number of cavities can be formed at the same time by using a cutting jig. Therefore, the invention method has an advantage of easy processing, is suitable for mass production of printed circuit boards, and is capable of reducing the manufacturing cost of printed circuit boards.

In addition, since cutting lines are formed by using a die in a state in which substrates (printed circuit boards) are stacked and then dried, prepregs of the substrates do not collapse, resulting in a remarkable reduction in a component connection defect rate.

Although the invention is described with reference to specific items such as specific structural elements, to merely some embodiments, and to drawings, such specific details disclosed herein are merely representative for purposes of helping more comprehensive understanding of the present invention. The present invention, however, is not limited to only the example embodiments set forth herein, and those skilled in the art will appreciate that the present invention can be embodied in many alternate forms.

1. A method of forming a cavity in a printed circuit board using a release film, the method comprising:
stacking a plurality of substrates in a thickness direction to form a stacked structure, each substrate including a prepreg and a copper clad circuit formed on a surface of the prepreg;
attaching a release film to an outer surface of the stacked structure;
demarcating a cavity region by forming a cutting line in the release film and the underlying prepreg; and
removing the released film and the underlying prepreg inside the demarcated cavity region, thereby forming a cavity.

2. The method according to claim 1, wherein the release film and the prepreg are simultaneously cut by using a die.

3. The method according to claim 2, wherein the demarcating of the cavity region is performed by using a cutting jig.

4. The method according to claim 3, wherein the multiple prepregs are cut at the same time during the demarcating of the cavity region.

5. The method according to claim 4, further comprising performing selective etching on a bottom surface of the cavity to form a circuit.

6. The method according to claim 5, wherein an adhesive strength between the release film and the prepreg is stronger than an adhesive strength between each of the prepregs.

7. The method according to claim 6, further comprising stacking a terminal connection substrate to be connected with an external component on the outer surface of the remaining release film.
